(19) United States
(12) Patent Application Publication
(10) Pub. No.: US 2020/0136071 A1
(43) Pub. Date: Apr. 30, 2020

(54) ORGANIC PHOTOVOLTAIC CELL

(71) Applicant: TAIYO YUDEN CO., LTD., Tokyo (JP)

(72) Inventors: Hidenori SOMEI, Takasaki-shi (JP); Takeyuki FUKUSHIMA, Takasaki-shi (JP)

(21) Appl. No.: 16/661,804

(22) Filed: Oct. 23, 2019

(30) Foreign Application Priority Data
Oct. 31, 2018 (JP) 2018-205921

(51) Int. Cl. H01L 51/44

(52) U.S. Cl. CPC H01L 51/442

(57) ABSTRACT

In an exemplary embodiment, an organic photovoltaic cell includes: a transparent electrode layer 21; an opposing electrode layer 32 facing the transparent electrode layer 21; an organic generation layer 25 provided between the transparent electrode layer 21 and the opposing electrode layer 32; a first electrode 21a connected to the transparent electrode layer 21; and a second electrode 21b connected to the opposing electrode layer 32 and provided, in plan view, on the side where the first electrode 21a is located.

### CROSS-REFERENCE TO RELATED APPLICATIONS

The present application claims priority to Japanese Patent Application No. 2018-205921, filed Oct. 31, 2018, the disclosure of which is incorporated herein by reference in its entirety including any and all particular combinations of the features disclosed therein.

### BACKGROUND

### Field of the Invention

The present invention relates to an organic photovoltaic cell.

### Description of the Related Art

Various types of photovoltaic cells are available, including amorphous silicon photovoltaic cells that use amorphous silicon to conduct photoelectric conversion, and are widely popular as batteries for supplying electric power to private residences and street lights. Meanwhile, organic photovoltaic cells offering higher low-illumination photoelectric conversion efficiencies than amorphous silicon photovoltaic cells have also been developed (refer to Patent Literatures 1 and 2, for example).

Several structures have also been proposed for drawing electric power from photovoltaic cells. For example, Patent Literature 3 proposes a structure comprising a rectangular photovoltaic cell with a positive electrode led out to one of its sides and a negative electrode led out to a side opposite the aforementioned side.

### BACKGROUND ART LITERATURES

[Patent Literature 1] Japanese Patent Laid-open No. 2017-28094

[Patent Literature 2] Japanese Patent Laid-open No. 2017-222640

[Patent Literature 3] International Patent Laid-open No. 2017/014182

### SUMMARY

However, leading out the positive electrode and the negative electrode in opposite directions, respectively, as in Patent Literature 3, creates a need to provide a positive electrode connector and a negative electrode connector separately. As a result, connecting the photovoltaic cell to these connectors becomes a troublesome task, which in turn reduces the convenience of the photovoltaic cell.

The present invention was made in light of the aforementioned problems, and its object is to increase the convenience of an organic photovoltaic cell.

The organic photovoltaic cell pertaining to the present invention comprises: a transparent electrode layer; an opposing electrode layer facing the transparent electrode layer; an organic generation layer provided between the transparent electrode layer and the opposing electrode layer; a first electrode connected to the transparent electrode layer; and a second electrode connected to the opposing electrode layer and provided, in plan view, on the side where the first electrode is located.

In the aforementioned organic photovoltaic cell, a cell region where the transparent electrode layer, opposing electrode layer, and organic generation layer overlap one another may be a polygon in plan view, and the first electrode and the second electrode may each extend, in plan view, from the same side of the polygon to the outside of the cell region.

In the aforementioned organic photovoltaic cell, a cell region where the transparent electrode layer, opposing electrode layer, and organic generation layer overlap one another may have a curved side in plan view, and the first electrode and the second electrode may each extend, in plan view, from the side to the outside of the cell region.

In the aforementioned organic photovoltaic cell, the first electrode and the second electrode may be positioned, in plan view, within an angle range of 90° from a point inside the cell region.

In the aforementioned organic photovoltaic cell, the cell region may be a circle or ellipse, and the point inside the cell region may correspond to the center point of the circle or ellipse.

The aforementioned organic photovoltaic cell may further have a transparent substrate with a first principal face on which light is incident and a second principal face on which the transparent electrode layer is formed, and the first electrode and the second electrode may be formed on the second principal face of the transparent substrate.

In the aforementioned organic photovoltaic cell, the first electrode may be formed by extending a part of the transparent electrode layer on the second principal face, and the second electrode may be positioned in the same plane with the transparent electrode layer.

The aforementioned organic photovoltaic cell may further have a supporting substrate that has been bonded to the transparent substrate via the opposing electrode layer, and the first electrode and the second electrode may each remain exposed instead of being covered by the supporting substrate.

According to the present invention, the convenience of an organic photovoltaic cell can be increased.

### BRIEF DESCRIPTION OF THE DRAWINGS

FIGS. 1A and 1B are perspective views (1) of the organic photovoltaic cell pertaining to Example 1 in the process of being manufactured.

FIGS. 2A and 2B are perspective views (2) of the organic photovoltaic cell pertaining to Example 1 in the process of being manufactured.

FIGS. 3A and 3B are perspective views (3) of the organic photovoltaic cell pertaining to Example 1 in the process of being manufactured.

FIGS. 4A and 4B are perspective views (4) of the organic photovoltaic cell pertaining to Example 1 in the process of being manufactured.

FIGS. 5A and 5B are perspective views (5) of the organic photovoltaic cell pertaining to Example 1 in the process of being manufactured.

FIG. 6 is a schematic plan view of the organic photovoltaic cell pertaining to Example 1.

FIG. 7 is a perspective view of the connector pertaining to Example 1.

FIG. 8 is a perspective view of the connector pertaining to Example 1, with the organic photovoltaic cell inserted in its slot.

FIG. 9 is a perspective view showing an example of how the connector pertaining to Example 1 is used.

FIGS. 10A and 10B are perspective views (1) of the organic photovoltaic cell pertaining to Example 2 in the process of being manufactured.

FIGS. 11A and 11B are perspective views (2) of the organic photovoltaic cell pertaining to Example 2 in the process of being manufactured.

FIG. 12 is a schematic plan view of the organic photovoltaic cell pertaining to Example 2.

FIGS. 13A and 13B are perspective views of the organic photovoltaic cell pertaining to Example 3 in the process of being manufactured.

FIGS. 14A and 14B are perspective views of the organic photovoltaic cell pertaining to Example 4 in the process of being manufactured.

FIGS. 15A and 15B are perspective views (1) of the organic photovoltaic cell pertaining to Example 5 in the process of being manufactured.

FIGS. 16A and 16B are perspective views (2) of the organic photovoltaic cell pertaining to Example 5 in the process of being manufactured.

FIGS. 17A and 17B are perspective views (3) of the organic photovoltaic cell pertaining to Example 5 in the process of being manufactured.

FIG. 18 is a perspective view (4) of the organic photovoltaic cell pertaining to Example 5 in the process of being manufactured.

FIG. 19 is a schematic plan view of the organic photovoltaic cell pertaining to Example 5.

FIGS. 20A and 20B are perspective views (1) of the organic photovoltaic cell pertaining to Example 6 in the process of being manufactured.

FIG. 21 is a perspective view (2) of the organic photovoltaic cell pertaining to Example 6 in the process of being manufactured.

FIGS. 22A and 22B are perspective views (1) of the organic photovoltaic cell pertaining to Example 7 in the process of being manufactured.

FIGS. 23A and 23B are perspective views (2) of the organic photovoltaic cell pertaining to Example 7 in the process of being manufactured.

FIGS. 24A and 24B are perspective views (3) of the organic photovoltaic cell pertaining to Example 7 in the process of being manufactured.

FIGS. 25A and 25B are perspective views (4) of the organic photovoltaic cell pertaining to Example 7 in the process of being manufactured.

FIG. 26 is a schematic plan view of the organic photovoltaic cell pertaining to Example 7.

FIG. 27A is a schematic plan view of the organic photovoltaic cell pertaining to the first example in Example 8, while FIG. 27B is a schematic plan view of the organic photovoltaic cell pertaining to the second example in Example 8.

FIG. 28A is a schematic plan view of the organic photovoltaic cell pertaining to the third example in Example 8, while FIG. 28B is a schematic plan view of the organic photovoltaic cell pertaining to another example of the third example of Example 8.

FIGS. 29A and 29B are perspective views of the organic photovoltaic cell pertaining to Example 9 in the process of being manufactured.

### DESCRIPTION OF THE SYMBOLS

20 Transparent substrate

20a First principal face

20b Second principal face

21 Transparent electrode layer

21a First electrode

21b Second electrode

22 Reverse-electron-transfer prevention layer

25a Semiconductor layer

25b Solid-state electrolyte layer

25, 86 Organic generation layer

26 Solid-state electrolyte precursor

27 UV-curable resin

31 Metal foil

32 Opposing electrode layer

33 Opposing electrode

34 Conductive paste

36 UV-curable resin

40, 70, 80, 90, 100 Organic photovoltaic cells

41 Side

50 Connector

51 Connector housing

52 Body

53 Cover

54 Slot

55 Contact

56 Jumper wire

58 Wiring board

83 Positive-electrode layer

84 Donor layer

85 Acceptor layer

87 Opposing electrode layer

### DETAILED DESCRIPTION OF EMBODIMENTS

Each example is explained below by referring to the drawings.

### EXAMPLE 1

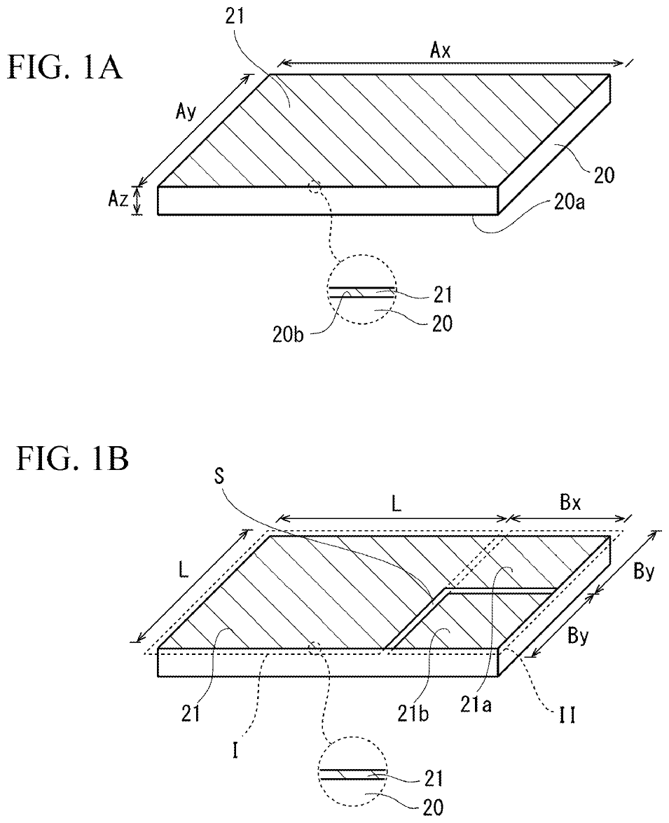

FIGS. 1A to 5B are perspective views of the organic photovoltaic cell pertaining to Example 1 in the process of being manufactured.

In this example, a dye-sensitized photovoltaic cell is produced, as follows, as an organic photovoltaic cell. First, as shown in FIG. 1A, a transparent substrate 20 with a first principal face 20a and a second principal face 20b, which are facing each other, is prepared.

Of these principal faces, the first principal face 20a becomes an incident face on which light is incident under practical use. Meanwhile, on the second principal face 20b, a fluorine-doped tin oxide (FTO) layer has been formed beforehand to a thickness of approx. 0.1 μm to 0.5 μm, as a transparent electrode layer 21. It should be noted that, in place of an FTO layer, any of the following may be formed as the transparent electrode layer 21: a zinc oxide layer; an indium-tin complex oxide layer; a laminate film consisting of an indium-tin complex oxide layer and a silver layer; and an antimony-doped tin oxide layer.

Also, the transparent substrate 20 is a glass substrate whose long side length Ax is in a range of 5 mm to 40 mm, such as 25 mm, and whose short side length Ay is in a range of 5 mm to 20 mm, such as 15 mm. Also, the thickness Az of the transparent substrate 20 is in a range of 0.1 mm to 3 mm, such as 1.1 mm. It should be noted that, in place of a glass substrate, a transparent plastic sheet may be used as the transparent substrate 20.

Next, as shown in FIG. 1B, the transparent electrode layer 21 is cut with a laser beam to form a slit S whose width is in a range of 10 μm to 300 μm, such as 100 μm, in the transparent electrode layer 21. This forms a first electrode 21a which is constituted by a part of the transparent electrode layer 21 corresponding to the electrode region II as if a part of the transparent electrode layer 21 corresponding to the cell region I of the transparent substrate 20 extends to the electrode region II. At the same time, the portion of the transparent electrode 21 being isolated from the first electrode 21a by the slit S becomes a second electrode 21b. This second electrode 21b is formed on a principal face of the transparent substrate 20 and positioned in the same plane with the transparent electrode layer 21 in the cell region I. Accordingly, both the first electrode 21a and the second electrode 21b are formed with the transparent electrode layer 21.

It should be noted that the cell region I represents a region where a solar battery cell is formed on the transparent substrate 20. Also, the electrode region II represents a region where the electrodes 21a, 21b for drawing electric power out of the solar battery cell are formed.

The shape and size of each of the regions I, II are not limited in any way. By way of example, the cell region I is a square region whose one side length L, in plan view, is in a range of 1 mm to 20 mm, such as 15 mm. Also, by way of example, the electrodes 21a, 21b in the electrode region II are each rectangular in plan view, and their long side length Bx (see FIG. 1B) is in a range of 4 mm to 20 mm, such as 10 mm. Also, by way of example, the short side length By (see FIG. 1B) of each of the electrodes 21a, 21b is in a range of 2 mm to 10 mm, such as 7.5 mm.

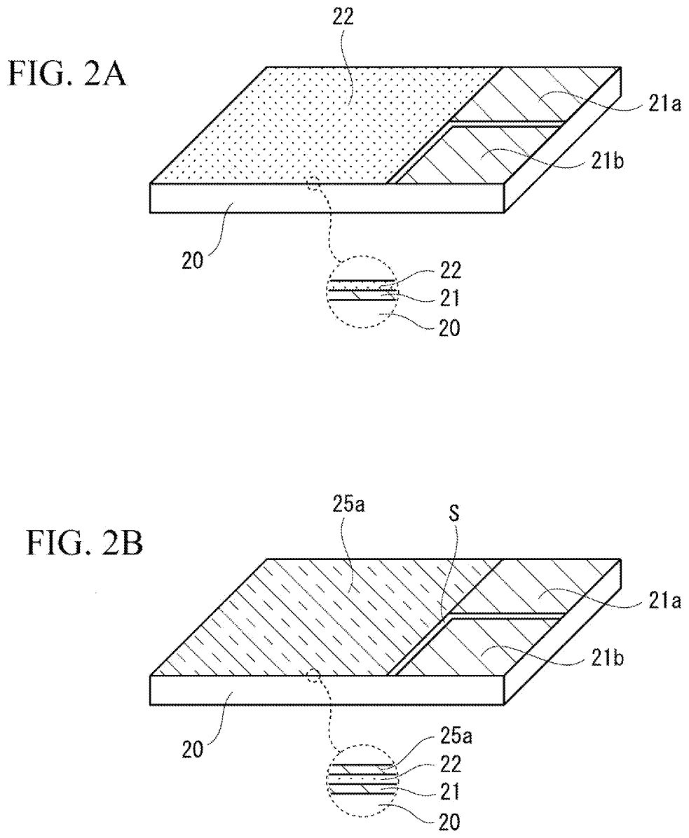

Next, as shown in FIG. 2A, an alcohol solution prepared from titanium alkoxide is applied on the transparent electrode layer 21 in the cell region I, after which the alcohol solution is heated and dried to form a reverse-electron-transfer prevention layer 22 to a thickness of approx. 5 nm to 0.1 μm. The drying temperature in this step is not limited in any way, so long as drying is performed at anywhere between 450° C. and 650° C., such as 550° C. or so.

Subsequently, as shown in FIG. 2B, a slurry in which titanium oxide particles of 5 nm to 50 nm in particle size have been dispersed is applied to a thickness of approx. 1 μm to 10 μm on the reverse-electron-transfer prevention layer 22 using the screen printing method, and then heated to remove the organic components, to form a semiconductor layer 25a. For this slurry, a titanium oxide paste manufactured by JGC Catalysts and Chemicals is used, for example. Also, the heating temperature of the slurry is in a range of 450° C. to 650° C., such as 550° C., while its drying time is in a range of 10 minutes to 120 minutes, such as 30 minutes or so.

It should be noted that the semiconductor particles that constitute the semiconductor layer 25a are not limited to titanium oxide particles; instead, the semiconductor layer 25a may be constituted by particles of an oxide of any of the following: Cd, Zn, In, Pb, Mo, W, Sb, Bi, Cu, Hg, Ti, Ag, Mn, Fe, V, Sn, Zr, Sr, Ga, Si, Cr, and Nb. Furthermore, the semiconductor layer 25a may be formed using particles of SrTiO₃, CaTiO₃ or other perovskite oxide.

Also, the region that forms the semiconductor layer 25a is the same square region as the cell region I (refer to FIG. 1B). Thereafter, the transparent substrate 20 is soaked in an organic solution containing a pigment to let the pigment adsorb onto the surface of the semiconductor particles that constitute the semiconductor layer 25a. This organic solution or the condition of soak therein is not limited in any way, either. For example, an organic solvent is prepared by mixing acetonitrile and t-butanol at a volume ratio of 1:1, with CYC-B11 (K) added to this organic solvent to a concentration of anywhere between 0.1 mM and 1 mM, such as 0.2 mM, and the resulting organic solution can be used in this step. Then, while keeping this organic solution at anywhere between 0° C. and 80° C., such as 50° C., the transparent substrate 20 can be soaked in the organic solvent for anywhere between 1 hour and 12 hours, such as 4 hours only, to let the pigment adsorb onto the semiconductor layer 25a.

Furthermore, the pigment is not limited to what is mentioned above, either, and any of metal complex pigments or organic pigments can be adsorbed onto the semiconductor layer 25a. Metal complex pigments include, for example, ruthenium-cis-diaqua-bipyridyl complexes, ruthenium-tris complexes, ruthenium-bis complexes, osmium-tris complexes, osmium-bis complexes, and other transition metal complexes. Additionally, zinc-tetra (4-carboxy phenyl) porphyrin and iron-hexacyanide complexes are also examples of metal complex pigments.

Also, organic pigments include, for example, 9-phenyl xanthene pigments, coumarin pigments, acridine pigments, triphenyl methane pigments, tetraphenyl methane pigments, quinone pigments, azo pigments, indigo pigments, cyanine pigments, merocyanine pigments, xanthene pigments, and carbazole compound pigments, and the like.

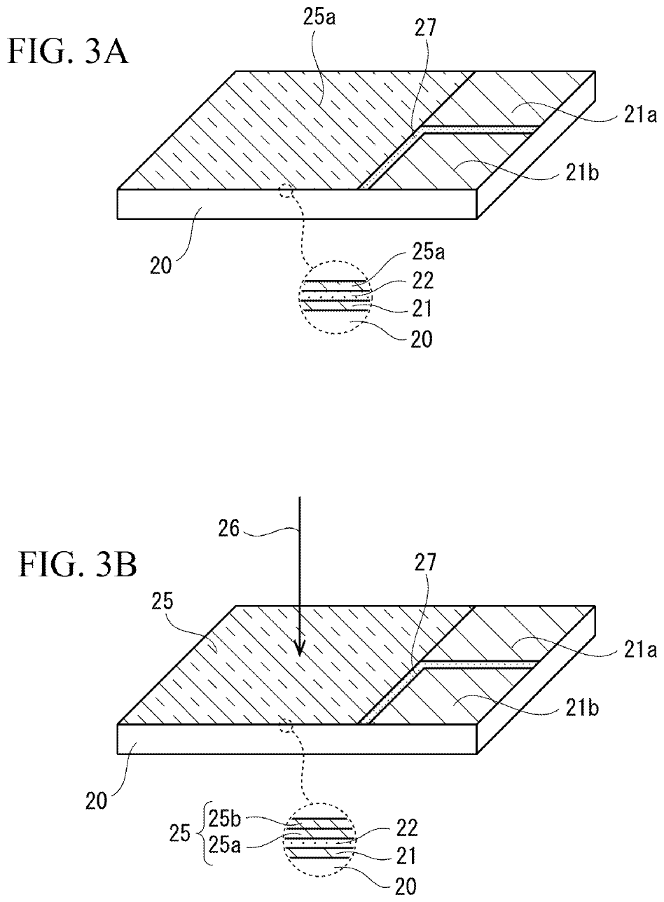

Subsequently, as shown in FIG. 3A, a UV-curable resin 27 is applied in the slit S and then ultraviolet light is irradiated to cure the UV-curable resin 27.

Next, the step shown in FIG. 3B is explained. First, iodine, 1,3-dimethyl imidazolium iodide (DMII), acetonitrile, and polyethylene oxide with a molecular weight of 1000000, are mixed together until homogenization, as a solid-state electrolyte precursor 26. Next, this solid-state electrolyte precursor 26 is dripped onto the semiconductor layer 25a by anywhere between 0.1 μL and 50 μL, such as 20 μL only, to adsorb the solid-state electrolyte precursor 26 on the semiconductor layer 25a. Then, the semiconductor layer 25a is heated to anywhere between 50° C. and 150° C., such as 100° C., with this condition maintained for anywhere between 1 minute and 60 minutes, such as 30 minutes, to volatilize the excess acetonitrile contained in the solid-state electrolyte precursor 26, so that the solid-state electrolyte precursor 26 remaining on the semiconductor layer 25a becomes a solid-state electrolyte layer 25b. Thereafter, the semiconductor layer 25a is returned to room temperature. It should be noted that, by applying the UV-curable resin 27 in the slit S beforehand, the solid-state electrolyte layer 25b and the second electrode 21b can be insulated by the UV-curable resin 27. Additionally, because of this UV-curable resin 27, the second electrode 21b can also be prevented from contacting the first electrode 21a.

Through the steps described so far, an organic generation layer 25 constituted by the semiconductor layer 25a and the solid-state electrolyte layer 25b, layered in this order, is obtained. It should be noted that the electrolyte contained in the solid-state electrolyte precursor 26 is not limited to DMII. For example, pyridinium salt, imidazolium salt, triazolium salt, or other iodine salt in solid state near room temperature may be used, or an ambient-temperature molten salt in molten state near room temperature may be used as an ion liquid. Such ambient-temperature molten salts include, for example, 1-methyl-3-propyl imidazolium iodide, 1-butyl-3-methyl imidazolium iodide (BMII), 1-ethyl-pyridinium iodide, and other quaternary ammonium salt iodide compounds, and the like.

Furthermore, the material for the solid-state electrolyte layer 25b is not limited to what is mentioned above, and any molten salt containing a redox couple, or oxadiazol compound, pyrazoline compound, or other organic semiconductor material, may be used as the material for the solid-state electrolyte layer 25b. Additionally, the solid-state electrolyte layer 25b may be formed by copper iodide, copper bromide, or other metal halogenated material. It should be noted that, in place of the solid-state electrolyte layer 25b, a liquid electrolyte layer or gelled electrolyte layer may be formed.

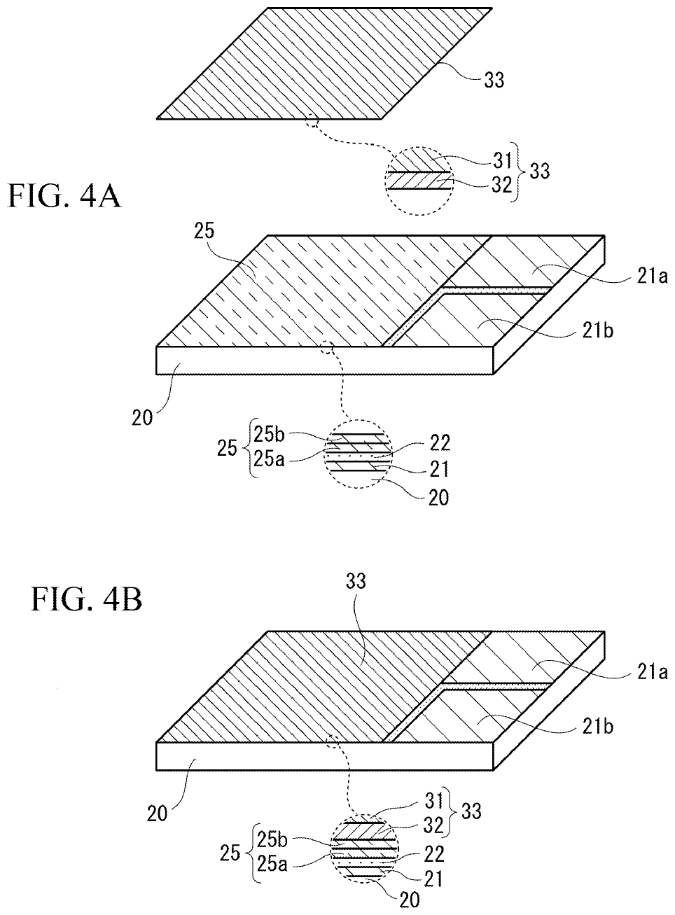

Subsequently, as shown in FIG. 4A, an opposing electrode 33 is placed above the organic generation layer 25. The layer structure of the opposing electrode 33 is not limited in any way. In this example, a titanium foil with a thickness of approx. 5 μm to 10 μm is prepared as a metal foil 31, and then a platinum layer is formed, as an opposing electrode layer 32, to a thickness of approx. 0.01 μm to 0.1 μm using the sputtering method over the entire surface of the principal face facing the transparent substrate 20, of the two principal faces of the metal foil 31, to produce the opposing electrode 33.

It should be noted that the material for the opposing electrode layer 32 may be, in addition to platinum as mentioned above, palladium, rhodium, indium, or other metal having catalytic function. Additionally, the opposing electrode layer 32 may be formed by graphite. Furthermore, the opposing electrode layer 32 may be formed by platinum-supporting carbon, indium-tin complex oxide, antimony-doped tin oxide, or fluorine-doped tin oxide. Other materials include poly(3,4-ethylene dioxythiophene) (PEDOT), polythiophene, and other organic semiconductors.

Next, as shown in FIG. 4B, the opposing electrode layer 32 is adhered to the organic generation layer 25 while eliminating air bubbles from between the organic generation layer 25 and the opposing electrode layer 32. It should be noted that performing this step in reduced-pressure atmosphere or in vacuum makes it difficult for air bubbles to remain between the organic generation layer 25 and the opposing electrode layer 32.

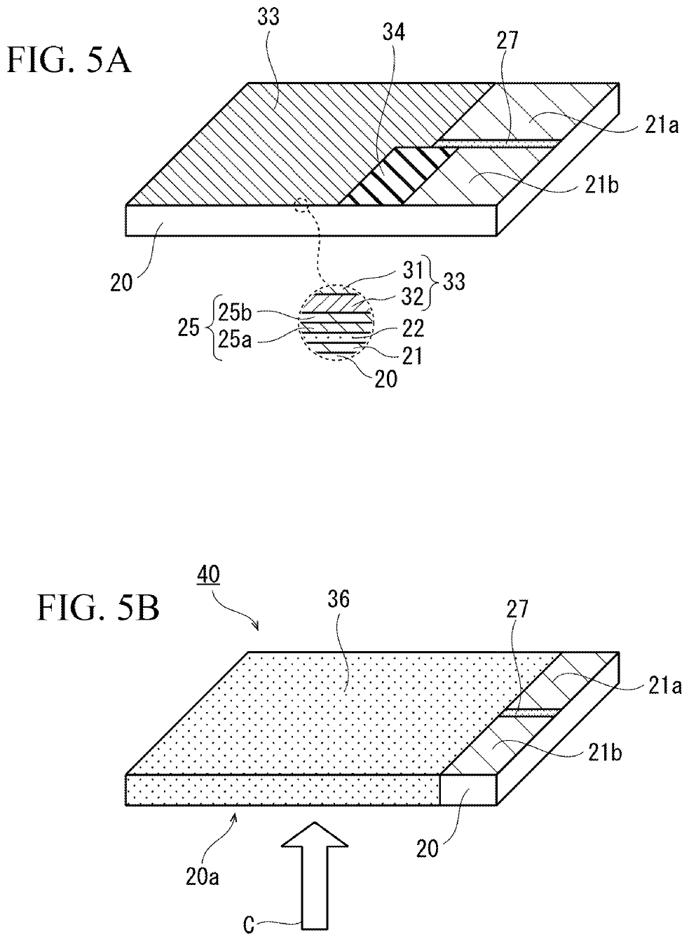

Next, as shown in FIG. 5A, a silver paste is applied on the opposing electrode 33 and the second electrode 21b, respectively, as a conductive paste 34. Thereafter, the conductive paste 34 is heated and solidified, to electrically connect the opposing electrode 33 and the second electrode 21b with the conductive paste 34. It should be noted that the heating temperature of the conductive paste 34 is not limited in any way, and it can be heated to temperatures between 50° C. and 150° C., such as 100° C. or so.

Next, as shown in FIG. 5B, the opposing electrode 33 and the side faces of the transparent substrate 20 are covered with a UV-curable resin 36 in such a way that the first electrode 21a and second electrode 21b will be exposed. It should be noted that the first principal face 20a of the transparent substrate 20 is not covered with the UV-curable resin 36, but remains exposed. Thereafter, the UV-curable resin 36 is cured by irradiating ultraviolet light, to protect the transparent electrode layer 21, organic generation layer 25, and opposing electrode 33 with the UV-curable resin 36, respectively. It should be noted that the center part of the principal face of the opposing electrode 33 may remain partially exposed, without being covered with the UV-curable resin 36.

The foregoing completes the basic structure of the organic photovoltaic cell 40 pertaining to this example. This organic photovoltaic cell 40 is a dye-sensitized photovoltaic cell as described above, where light C incident on the first principal face 20a of the transparent substrate 20 transmits through the transparent electrode layer 21 and reaches the organic generation layer 25 to produce approx. 0.6 V of electromotive force between the transparent electrode layer 21 and the opposing electrode 33. It should be noted that, in this example, the first electrode 21a connected to the transparent electrode layer 21 becomes a negative electrode, while the second electrode 21b connected to the opposing electrode 33 becomes a positive electrode.

In particular, dye-sensitized photovoltaic cells provide greater electromotive forces than silicon solar batteries under weak sunlight in the winter and in the morning and evening hours, and thus are suitable as batteries for IoT (Internet of Things) devices used under weak light.

Also, in this example, the transparent electrode layer 21 and electrodes 21a, 21b are formed on the second principal face 20b (refer to FIG. 1A) of the transparent substrate 20, which means light C incident on the first principal face 20a is not obstructed by the electrodes 21a, 21b, and therefore light C can be effectively utilized for photoelectric conversion.

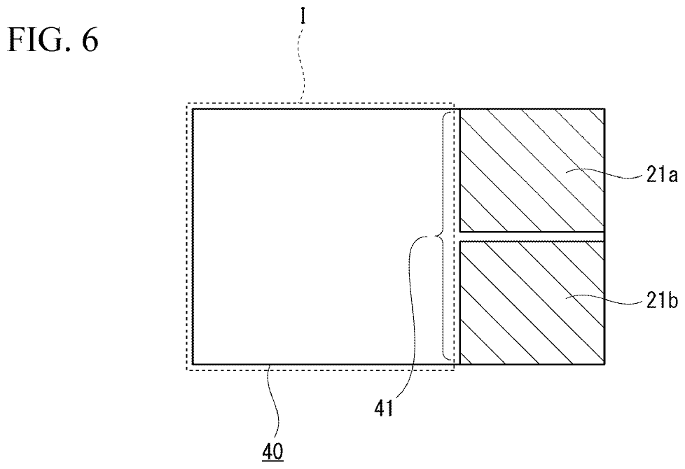

FIG. 6 is a schematic plan view of this organic photovoltaic cell 40. As shown in FIG. 6, the cell region I is a rectangular region where all of the transparent electrode layer 21, organic generation layer 25, and opposing electrode layer 32 overlap one another in plan view. In this example, the second electrode 21b is led out to the side of the organic photovoltaic cell 40 where the first electrode 21 is located, so that the electrodes 21a, 21b extend from the same side 41 of the cell region I to the outside of the cell region I.

Next, the connector used in conjunction with this organic photovoltaic cell 40 is explained.

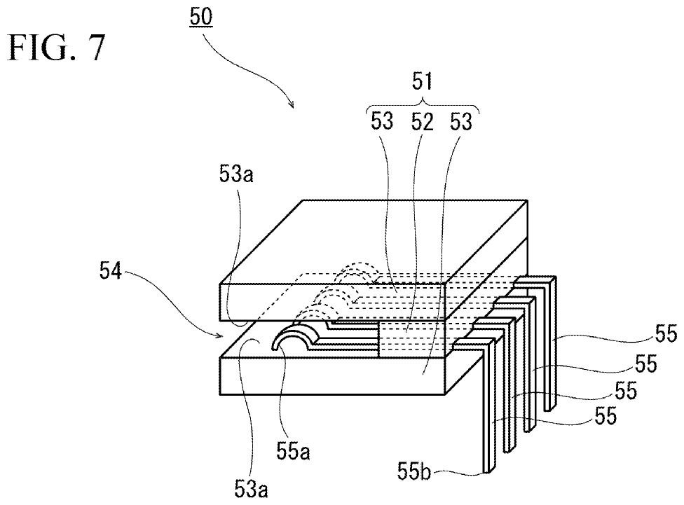

FIG. 7 is a perspective view of the connector pertaining to this example. As shown in FIG. 7, this connector 50 has a connector housing 51 in which the organic photovoltaic cell 40 is stored. The connector housing 51 has a laminar body 52 and a pair of laminar covers 53 firmly fixed on both sides of the body 52, and a slot 54 is defined by these body 52 and covers 53. It should be noted that the body 52 and covers 53 are each formed by a resin.

Also, opposing faces 53a of the pair of covers 53 are roughly parallel with each other, and this allows the organic photovoltaic cell 40 to be smoothly inserted in the slot 54. Provided in the slot 54 are multiple cantilever-shaped contacts 55. Each contact 55 is made of a thin sheet of copper or other metal, and integrally provided with the connector housing 51 using an insert die. It should be noted that, instead of using an insert die, each contact 55 may be press-fit into the connector housing 51.

Also, one end 55a of each contact 55 is provided in a manner elastically deformable in up and down directions inside the slot 54. Meanwhile, the other end 55b of each contact 55 is bent orthogonally to the opposing faces 53a of the covers 53 and can be freely inserted into an insertion hole in a wiring board which is not illustrated.

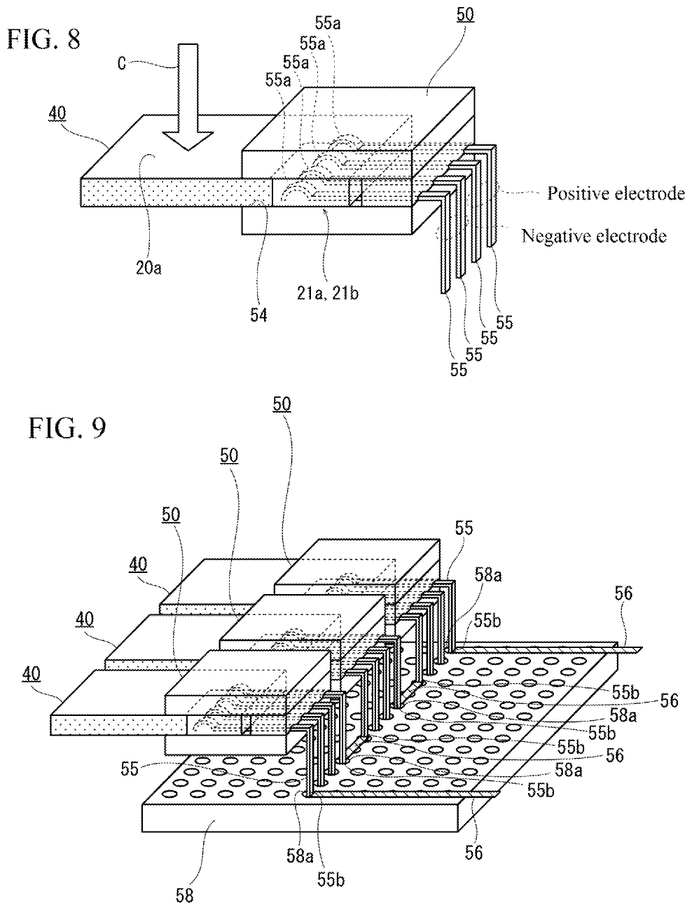

FIG. 8 is a perspective view of the slot 54 with the organic photovoltaic cell 40 inserted in it. As shown in FIG. 8, the organic photovoltaic cell 40 is inserted in the slot 54 from the electrode 21a, 21b side, with the first principal face 20a of the transparent substrate 20 facing the incident direction of light C. This way, one end 55a of each contact 55 makes contact with the surface of either the first electrode 21a or second electrode 21b, allowing the electric power generated by the organic photovoltaic cell 40 to be drawn from each contact 55.

Particularly, in this example, the second electrode 21b is provided on the same side of the organic photovoltaic cell 40 as the first electrode 21a, as shown in FIG. 6, which makes it easy to connect and remove these electrodes 21a, 21b to/from the connector 50, and the convenience of the organic photovoltaic cell 40 can be increased as a result.

It should be noted that, in this example, adjacent two of the four contacts 55 are used as a negative electrode, and these two contacts 55 are connected to the first electrode 21a. Also, the remaining two contacts 55 are used as a positive electrode, and these contacts 55 are connected to the second electrode 21b.

FIG. 9 is a perspective view showing an example of how the connector 50 is used. The example of FIG. 9 assumes that a breadboard is used as a wiring board 58 and that three connectors 50 are mounted on this wiring board 58. In this case, the other end 55b of the contact 55 of each connector 50 is inserted into an insertion hole 58a in the wiring board 58. Also, in this example, organic photovoltaic cells 40 are connected in series using jumper wires 56. This way, high voltage of approx. 1.8 V (=3×0.6 V) can be obtained; in other words, voltage higher than what is expected from use of a single organic photovoltaic cell 40 can be obtained.

### EXAMPLE 2

In this example, the opposing electrode 33 has a planar shape as described below, which is different from Example 1.

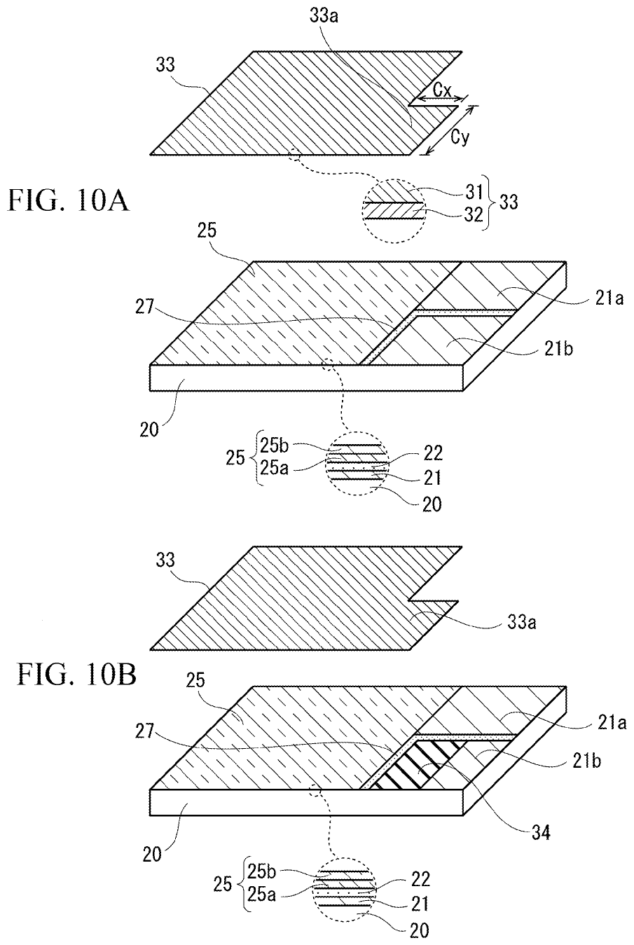

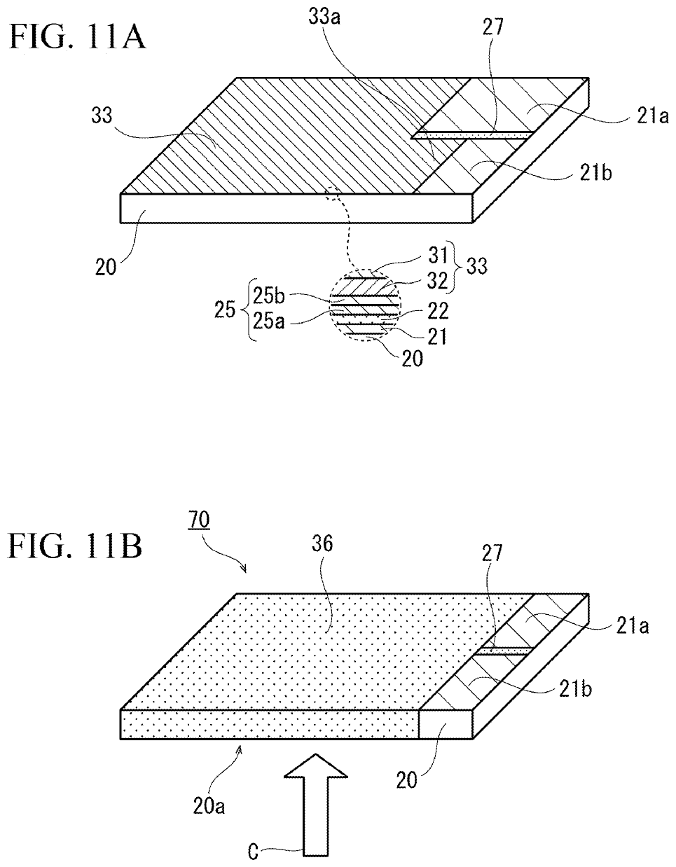

FIGS. 10A, 10B, 11A, and 11B are perspective views of the organic photovoltaic cell pertaining to this example in the process of being manufactured. It should be noted that, in these figures, the same elements as those in Example 1 are denoted by the same symbols used in Example 1, and not explained below.

First, the steps per FIGS. 1A to 4A as explained in connection with Example 1 are performed to place the opposing electrode 33 above the organic generation layer 25, as shown in FIG. 10A. The layer constitution of the opposing electrode 33 is similar to that in Example 1, and an opposing electrode 33 constituted by a platinum layer formed, as an opposing electrode layer 32, on a titanium foil or other metal foil 31, is used.

It should be noted that, while the opposing electrode 33 was rectangular in plan view in Example 1, an extension part 33a that overlaps the second electrode 21b is provided for the opposing electrode 33 in this example. The size of this extension part 33a is not limited in any way. For example, the projection amount Cx of the extension part 33a is approx. 1 mm to 10 mm, while the width Cy of the extension part 33a is approx. 2 mm to 10 mm.

Next, as shown in FIG. 10B, a silver paste is applied, as a conductive paste 34, on the portion of the second electrode 21b closer to the organic generation layer 25. Next, as shown in FIG. 11A, the opposing electrode layer 32 is adhered to the organic generation layer 25 in reduced-pressure atmosphere or in vacuum, while at the same time the extension part 33a and the second electrode 21b are connected to each other via the conductive paste 34. Thereafter, the conductive paste 34 is heated to anywhere between 50° C. and 150° C., such as 100° C., to be solidified.

Next, as shown in FIG. 11B, the opposing electrode 33 and the side faces of the transparent substrate 20 are covered with a UV-curable resin 36 in such a way that the first electrode 21a and second electrode 21b will be exposed. It should be noted that the first principal face 20a on which light C is incident is not covered with the UV-curable resin 36, but remains exposed. Thereafter, the UV-curable resin 36 is cured by irradiating ultraviolet light, to protect the transparent electrode layer 21, organic generation layer 25, and opposing electrode 33 with the UV-curable resin 36, respectively. It should be noted that, as in Example 1, the center part of the principal face of the opposing electrode 33 may remain partially exposed, without being covered with the UV-curable resin 36.

The foregoing completes the basic structure of the organic photovoltaic cell 70 pertaining to this example.

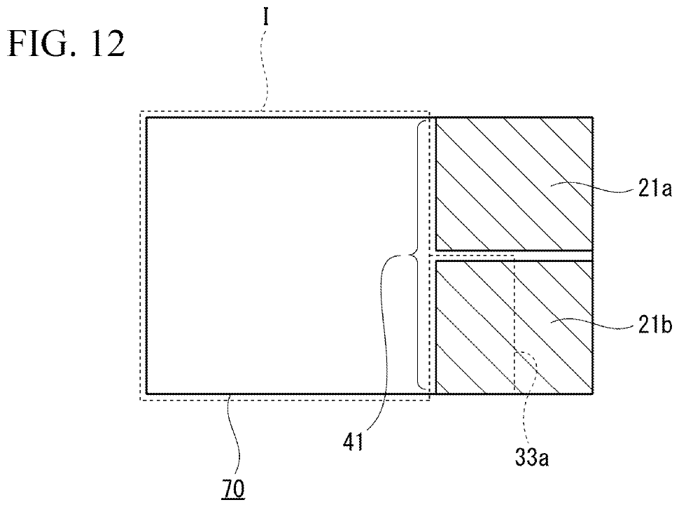

FIG. 12 is a schematic plan view of this organic photovoltaic cell 70. As shown in FIG. 12, while the extension part 33a is provided for the opposing electrode 33 in this example, the cell region I where all of the transparent electrode layer 21, organic generation layer 25, and opposing electrode layer 32 overlap one another in plan view is also rectangular, as in Example 1.

Additionally, as in Example 1, providing the second electrode 21b on the side of the organic photovoltaic cell 70 where the first electrode 21a is located makes the electrodes 21a, 21b extend outward from the same side 41 of the cell region I. This makes it easy to connect and remove the electrodes 21a, 21b to/from the slot 54 in the connector 50 (refer to FIG. 7), and the convenience of the organic photovoltaic cell 70 can be increased as a result.

### EXAMPLE 3

This example differs from Example 2 only in the layer constitution of the opposing electrode 33, and is identical to Example 2 in other respects.

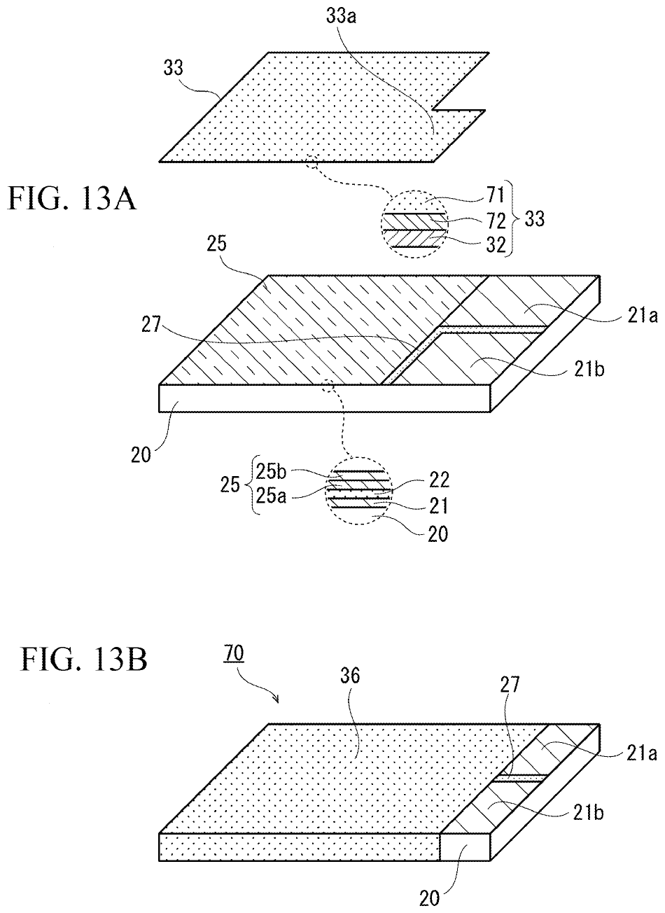

FIGS. 13A, 13B are perspective views of the organic photovoltaic cell pertaining to this example in the process of being manufactured. It should be noted that, in these figures, the same elements as those in Examples 1 and 2 are denoted by the same symbols used in these examples and not explained below.

First, as shown in FIG. 13A, the opposing electrode 33 is placed above the organic generation layer 25 in a manner similar to FIG. 10A of Example 2. In this example, however, an opposing electrode 33 constituted by a base metal layer 72 and an opposing electrode layer 32, formed in this order on top of a resin film 71, is used. This resin film 71 is, for example, a PEN (polyethylene naphthalate) film with a thickness of approx. 10 μm to 200 μm.

Also, the base metal layer 72 is a titanium layer with a thickness of approx. 1 μm to 10 μm, formed by the sputtering method. Additionally, the opposing electrode layer 32 is a platinum layer with a thickness of approx. 0.1 μm to 0.3 μm, formed by the sputtering method, as in Example 1. It should be noted that, as in Example 2, an extension part 33a is provided for the opposing electrode 33, and the opposing electrode layer 32 and base metal layer 72 are also formed on this extension part 33a.

Hereafter, the steps per FIGS. 10B to 11B as explained in connection with Example 2 are performed to complete the basic structure of the organic photovoltaic cell 70 pertaining to this example as shown in FIG. 13B. In this example, too, the second electrode 21b is provided on the side of the organic photovoltaic cell 70 where the first electrode 21a is located, as explained in FIG. 12 of Example 2, and this makes it easy to connect and remove these electrodes 21a, 21b to/from the connector 50 (refer to FIG. 7). It should be noted that, while FIG. 13B illustrates a case where the principal face of the opposing electrode 33 is entirely covered with the UV-curable resin 36, the center part of this principal face may remain partially exposed, without being covered with the UV-curable resin 36, as in Example 1.

### EXAMPLE 4

This example differs from Example 3 only in the layer constitution of the opposing electrode 33, and is identical to Example 3 in other respects.

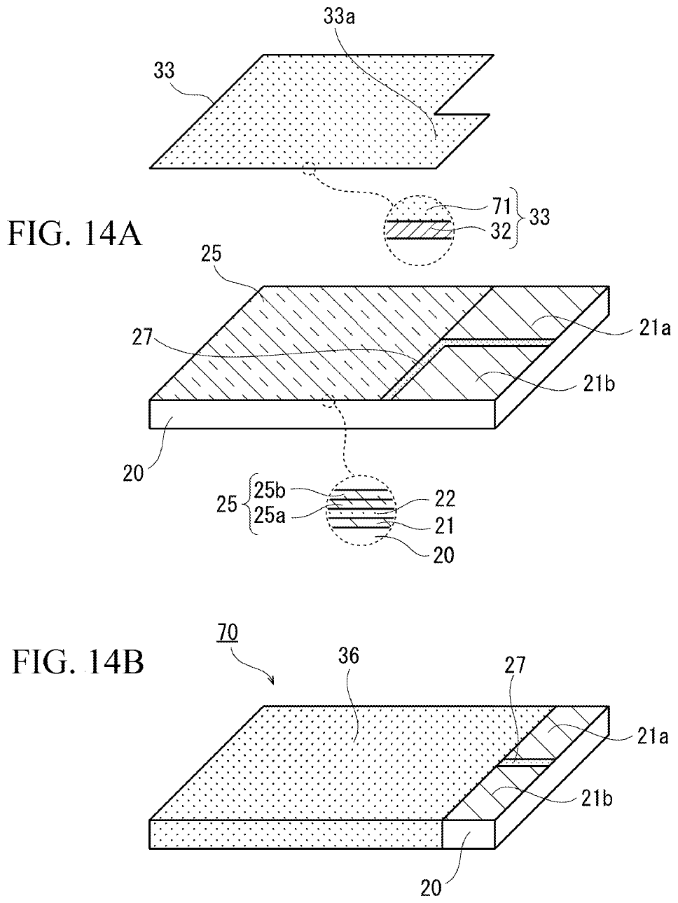

FIGS. 14A and 14B are perspective views of the organic photovoltaic cell pertaining to this example in the process of being manufactured. It should be noted that, in these figures, the same elements as those in Examples 1 to 3 are denoted by the same symbols used in these examples and not explained below. First, as shown in FIG. 14A, the opposing electrode 33 is placed above the organic generation layer 25 in a manner similar to FIG. 13A of Example 3.

In this example, however, the base metal layer 72 used in Example 3 is eliminated from the opposing electrode 33, and the platinum layer is directly formed on the resin film 71, as the opposing electrode layer 32, using the sputtering method. Thereafter, the steps per FIGS. 10B to 11B as explained in connection with Example 2 are performed, to complete the basic structure of the organic photovoltaic cell 70 pertaining to this example as shown in FIG. 14B.

In this example, too, the electrodes 21a, 21b are provided on the same side of the organic photovoltaic cell 70, as shown in FIG. 12 of Example 2, and this makes it easy to connect and remove the electrodes 21a, 21b to/from the connector 50 (refer to FIG. 7). It should be noted that, while FIG. 14B illustrates a case where the principal face of the opposing electrode 33 is entirely covered with the UV-curable resin 36, the center part of this principal face may remain partially exposed, without being covered with the UV-curable resin 36, as in Example 1.

### EXAMPLE 5

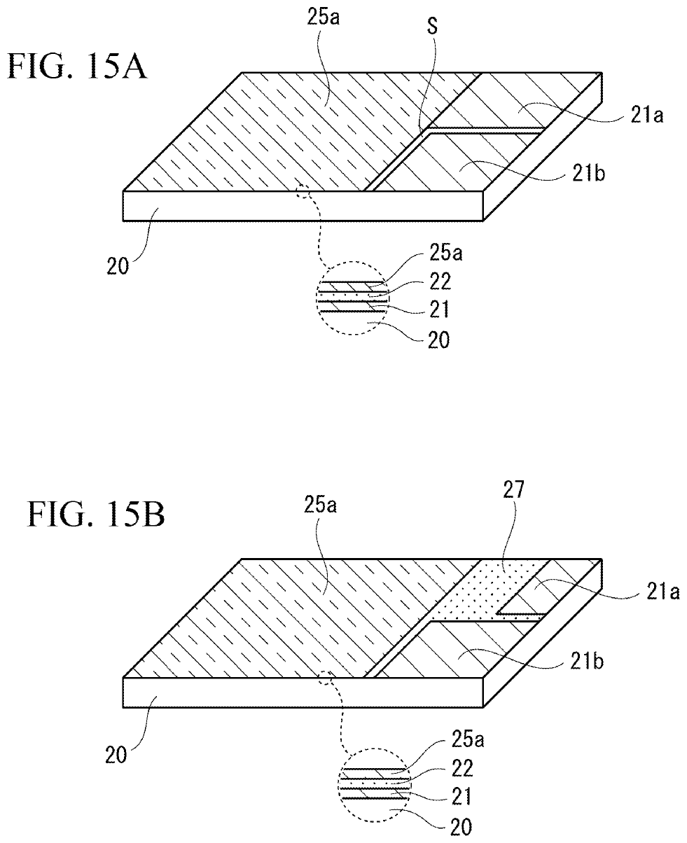

In this example, a glass substrate is used on the positive-electrode side as described below. FIGS. 15A to 18 are perspective views of the organic photovoltaic cell pertaining to this example in the process of being manufactured. It should be noted that, in these figures, the same elements as those in Examples 1 to 4 are denoted by the same symbols used in these examples and not explained below.

First, the steps per FIGS. 1A to 2B of Example 1 are performed to obtain a structure where the transparent electrode layer 21, reverse-electron-transfer prevention layer 22, and semiconductor layer 25a are formed, in this order, on top of the transparent substrate 20, as shown in FIG. 15A. Next, as shown in FIG. 15B, a UV-curable resin 27 is applied on the portion of the first electrode 21a closer to the semiconductor layer 25a and also in the slit S. Then, ultraviolet light is irradiated to cure the UV-curable resin 27.

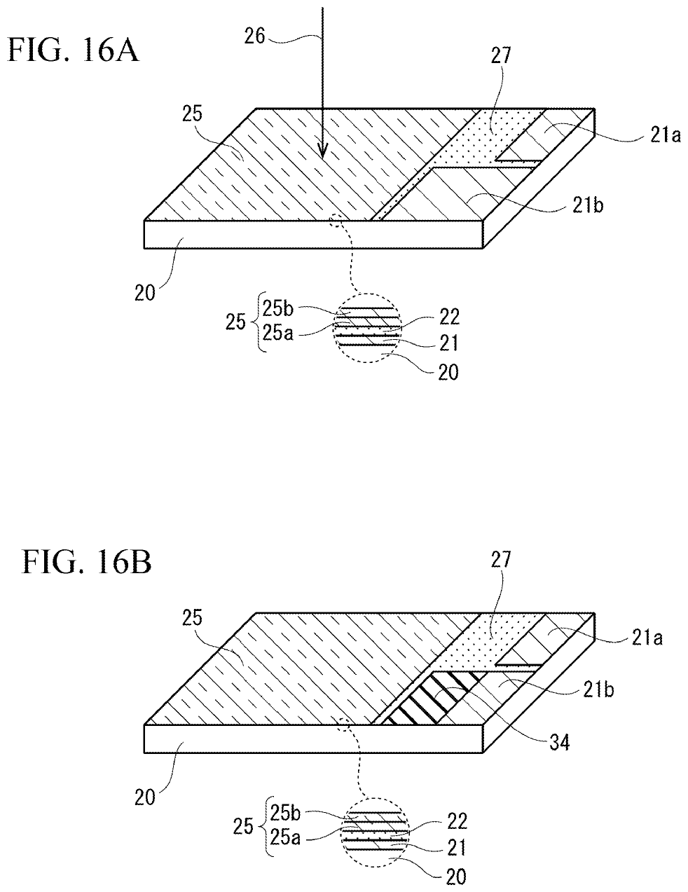

Subsequently, as shown in FIG. 16A, the solid-state electrolyte precursor 26 is dripped onto the semiconductor layer 25a by anywhere between 0.1 μL to 50 μL, such as 20 μL only, to adsorb the solid-state electrolyte precursor 26 on the semiconductor layer 25a. For this solid-state electrolyte precursor 26, a solution prepared as a homogeneous mixture of iodine, 1,3-dimethyl imidazolium iodide (DMII), acetonitrile, and polyethylene oxide with a molecular weight of 1000000, is used.

Furthermore, the semiconductor layer 25a is heated to volatilize the excess acetonitrile contained in the solid-state electrolyte precursor 26, so that the solid-state electrolyte precursor 26 remaining on the semiconductor layer 25a becomes a solid-state electrolyte layer 25b. It should be noted that the heating temperature and heating time of the semiconductor layer 25a are not limited in any way. The heating temperature can be anywhere between 50° C. and 150° C., such as 100° C. Also, the heating time can be anywhere between 1 minute and 60 minutes, such as 30 minutes. Thereafter, the semiconductor layer 25a is returned to room temperature.

Through the steps described so far, an organic generation layer 25 constituted by the semiconductor layer 25a and the solid-state electrolyte layer 25b, stacked in this order, is obtained. Next, as shown in FIG. 16B, a silver paste is applied, as a conductive paste 34, on the portion of the second electrode 21b closer to the organic generation layer 25.

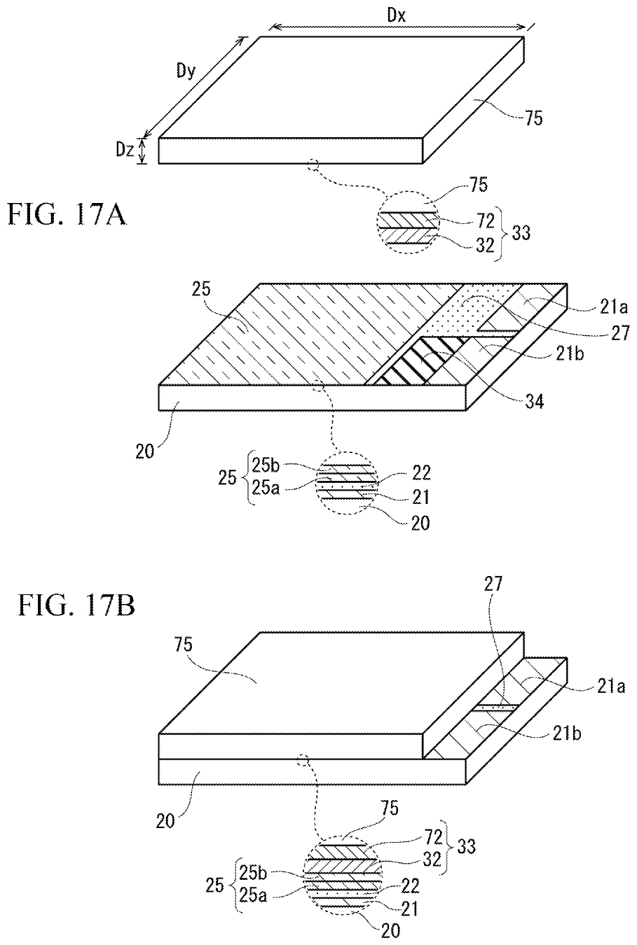

Subsequently, as shown in FIG. 17A, a glass substrate is placed, as a supporting substrate 75, above the transparent substrate 20. Also, over the entire surface of the principal face facing the transparent substrate 20, of the two principal faces of this supporting substrate 75, a base metal layer 72 and an opposing electrode layer 32 are formed in this order, as an opposing electrode 33.

Of these, the base metal layer 72 is, for example, a titanium layer with a thickness of 1 μm to 10 μm, formed by the sputtering method. Additionally, the opposing electrode layer 32 is, for example, a platinum layer with a thickness of approx. 0.1 μm to 0.3 μm, formed by the sputtering method. Meanwhile, while the size of the supporting substrate 75 is not limited in any way, its long side length Dx is in a range of 5 mm to 30 mm, such as 17 mm, while its short side length Dy is in a range of 5 mm to 20 mm, such as 15 mm. Also, the thickness Dz of the supporting substrate 75 is in a range of 0.1 mm to 3 mm, such as 1.1 mm.

Next, as shown in FIG. 17B, the transparent substrate 20 and the supporting substrate 75 are bonded together in such a way that the electrodes 21a, 21b are exposed from the supporting substrate 75. This way, the organic generation layer 25 adheres to the opposing electrode layer 32, while at the same time the opposing electrode layer 32 and the second electrode 21b are connected to each other via the conductive paste 34. It should be noted that performing this step in reduced-pressure atmosphere or in vacuum makes it easy to eliminate air bubbles from between the organic generation layer 25 and the opposing electrode layer 32.

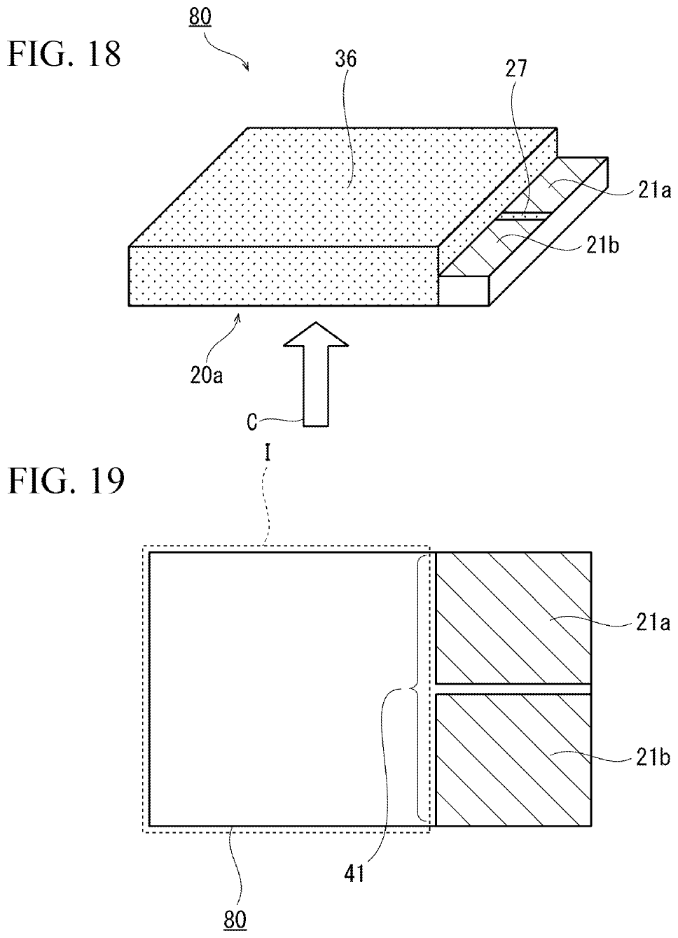

Thereafter, the conductive paste 34 is heated to anywhere between 50° C. and 150° C., such as 100° C., to be solidified. Next, as shown in FIG. 18, the portions of the transparent substrate 20 and supporting substrate 75, excluding the first principal face 20a on which light C is incident and the electrodes 21a, 21b, are covered with a UV-curable resin 36. Thereafter, the UV-curable resin 36 is cured by irradiating ultraviolet light, to protect the transparent electrode layer 21, organic generation layer 25, and opposing electrode 33 with the UV-curable resin 36, respectively. It should be noted that the center part of the principal face of the supporting substrate 75 may remain partially exposed, without being covered with the UV-curable resin 36.

The foregoing completes the basic structure of the organic photovoltaic cell 80 pertaining to this example.

According to this example as described above, the organic photovoltaic cell 80 can be reinforced by bonding the transparent substrate 20 and the supporting substrate 75 together.

FIG. 19 is a schematic plan view of this organic photovoltaic cell 80. As shown in FIG. 19, the cell region I where all of the transparent electrode layer 21, organic generation layer 25, and opposing electrode layer 32 overlap one another in plan view is also rectangular in this example, as in Examples 1 to 4.

Additionally, the second electrode 21b is provided on the side of the organic photovoltaic cell 80 where the first electrode 21a is located, so that the electrodes 21a, 21b extend from one side 41 of the cell region Ito the outside of the cell region I. This makes it easy to connect and remove the electrodes 21a, 21b to/from the connector 50 (refer to FIG. 7), as in Examples 1 to 4.

### EXAMPLE 6

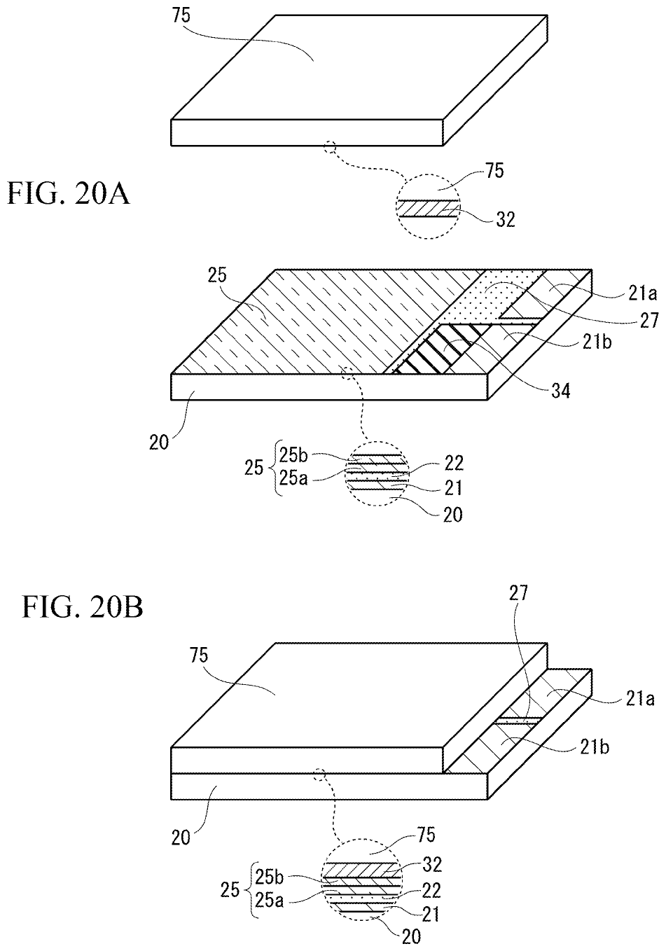

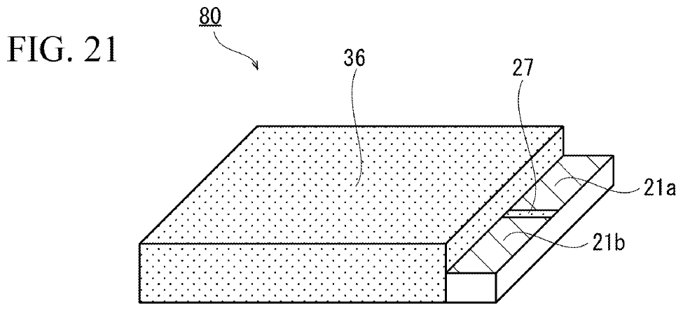

As in Example 5, a supporting substrate 75 is also used in this example. FIGS. 20A, 20B, and 21 are perspective views of the organic photovoltaic cell pertaining to this example in the process of being manufactured. It should be noted that, in these figures, the same elements as those in Examples 1 to 5 are denoted by the same symbols used in these examples and not explained below.

First, in a manner similar to the step per FIG. 17A of Example 5, the supporting substrate 75 is placed above the transparent substrate 20 as shown in FIG. 20A. However, this example is different from Example 5 in that the base metal layer 72 is not formed on the supporting substrate 75, but the platinum layer is directly formed on the supporting substrate 75 as the opposing electrode layer 32 instead.

Subsequently, as shown in FIG. 20B, the transparent substrate 20 and the supporting substrate 75 are bonded together to adhere the opposing electrode layer 32 to the organic generation layer 25. At the same time, the opposing electrode layer 32 and the second electrode 21b are connected to each other via the conductive paste 34. Thereafter, the conductive paste 34 is heated to anywhere between 50° C. and 150° C., such as 100° C., to be solidified.

Next, as shown in FIG. 21, a UV-curable resin 36 is applied in the same areas as indicated in Example 5, after which ultraviolet light is irradiated to cure the UV-curable resin 36. As in Example 5, the center part of the principal face of the supporting substrate 75 may remain partially exposed, without being covered with the UV-curable resin 36. The foregoing completes the basic structure of the organic photovoltaic cell 80 pertaining to this example.

In this example, too, as described above, the second electrode 21b is provided on the side of the organic photovoltaic cell 80 where the first electrode 21a is located, as in Example 5. This makes it easy to connect and remove the electrodes 21a, 21b to/from the connector 50.

### EXAMPLE 7

Departing from Examples 1 to 6, this example manufactures an organic thin-film photovoltaic cell as an organic photovoltaic cell.

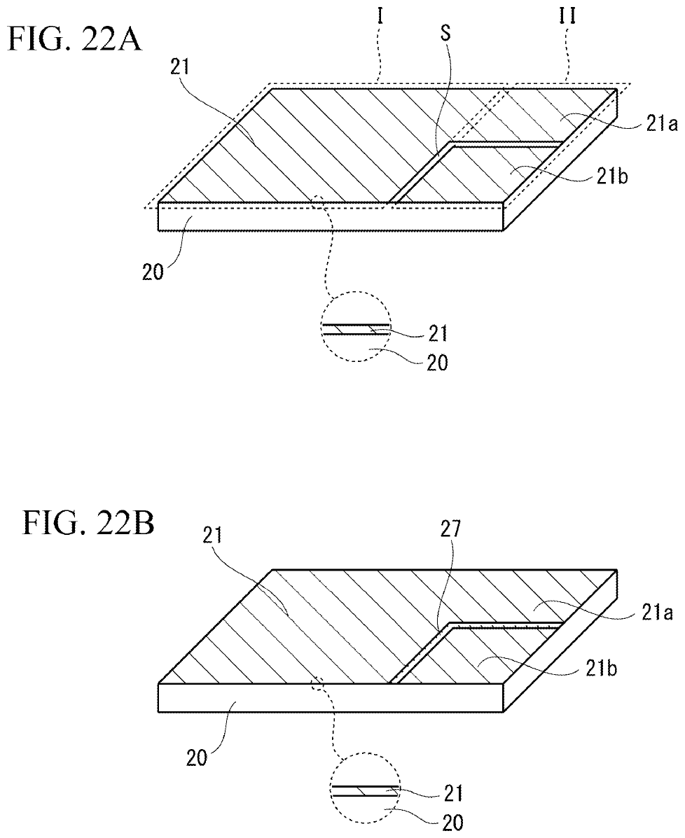

FIGS. 22A to 25B are perspective views of the organic photovoltaic cell pertaining to this example in the process of being manufactured. It should be noted that, in these figures, the same elements as those in Examples 1 to 6 are denoted by the same symbols used in these examples and not explained below. First, the steps per FIGS. 1A and 1B as explained in connection with Example 1 are performed to obtain, as shown in FIG. 22A, a structure where the transparent electrode layer 21 is formed in the cell region I and the electrodes 21a, 21b are formed in the electrode region II.

Next, as shown in FIG. 22B, a UV-curable resin 27 is applied in the slit S and, furthermore, ultraviolet light is irradiated to cure the UV-curable resin 27.

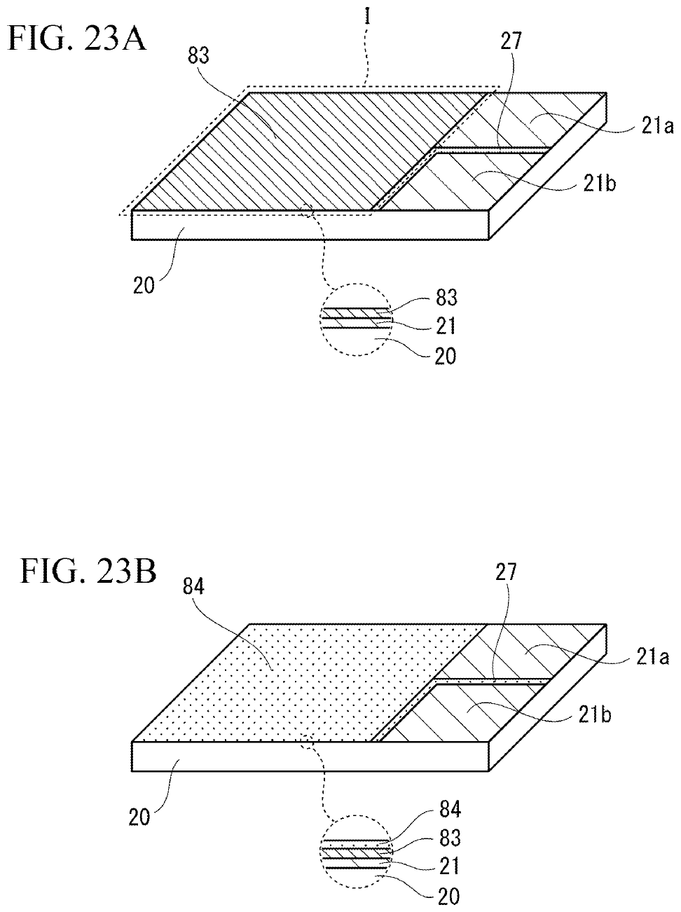

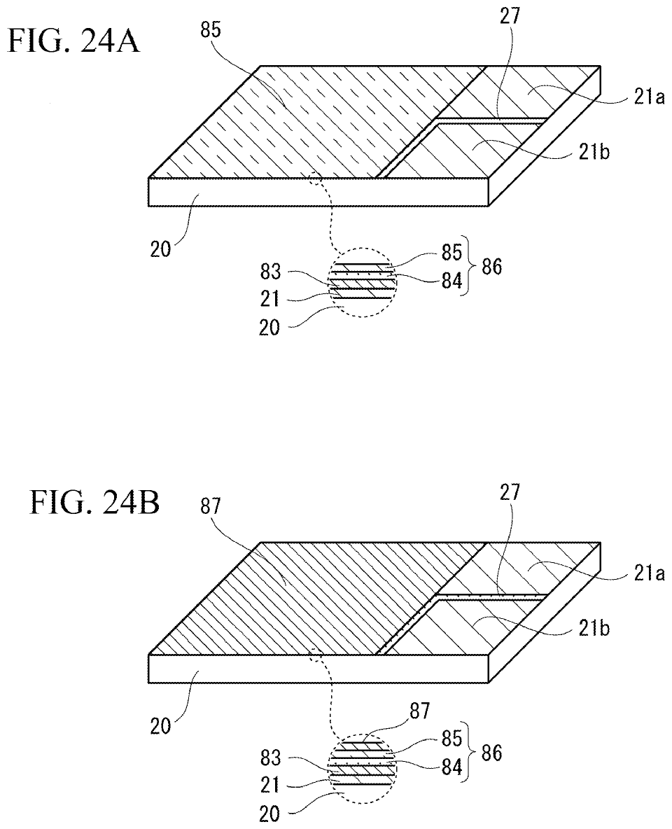

Subsequently, as shown in FIG. 23A, a conductive polymer is applied on the transparent electrode layer 21 in the cell region I and then dried at temperatures between 80° C. and 150° C., such as 120° C. or so, to form a light-transmitting positive-electrode layer 83. The conductive polymer that serves as the material for the positive-electrode layer 83 is not limited in any way, but in this example, a conductive polymer containing poly(3,4-ethylene dioxythiophene) (PEDOT) and polystyrene sulfonate (PSS) is used.

Next, as shown in FIG. 23B, poly(3-hexylthiophene-2,5-diyl) (P3HT), which is an organic semiconductor polymer, is applied on the positive-electrode layer 83 using the spin-coating method, and then dried at temperatures between 50° C. and 150° C., such as 100° C. or so, to obtain a donor layer 84. It should be noted that the organic semiconductor polymer that has been applied on the first electrode 21a and second electrode 21b is wiped off before it dries, so as to prevent the donor layer 84 from being formed on these electrodes 21a, 21b.

Subsequently, as shown in FIG. 24A, a solution of PCBM (phenyl C₆₁ butyric acid methyl ester) is applied on the donor layer 84 using the spin-coating method, and then heated and dried, to form an acceptor layer 85. The drying causes the respective solvents contained in the donor layer 84 and the acceptor layer 85, to evaporate.

It should be noted that the drying temperature and drying time are not limited in any way. The drying temperature can be in a range of 100° C. to 200° C., such as 150° C. Also, the drying time can be in a range of 5 minutes to 60 minutes, such as 30 minutes. Furthermore, the PCBM solution that has been applied on the electrodes 21a, 21b is wiped off before it dries, so as to prevent the acceptor layer 85 from being formed on these electrodes 21a, 21b.

Through the steps described so far, an organic generation layer 86 constituted by the donor layer 84 and the acceptor layer 85, formed in this order, is obtained. Next, as shown in FIG. 24B, an aluminum layer is formed, as an opposing electrode layer 87, on this organic generation layer 86 to a thickness of approx. 0.1 μm to 10 μm using the vapor deposition method.

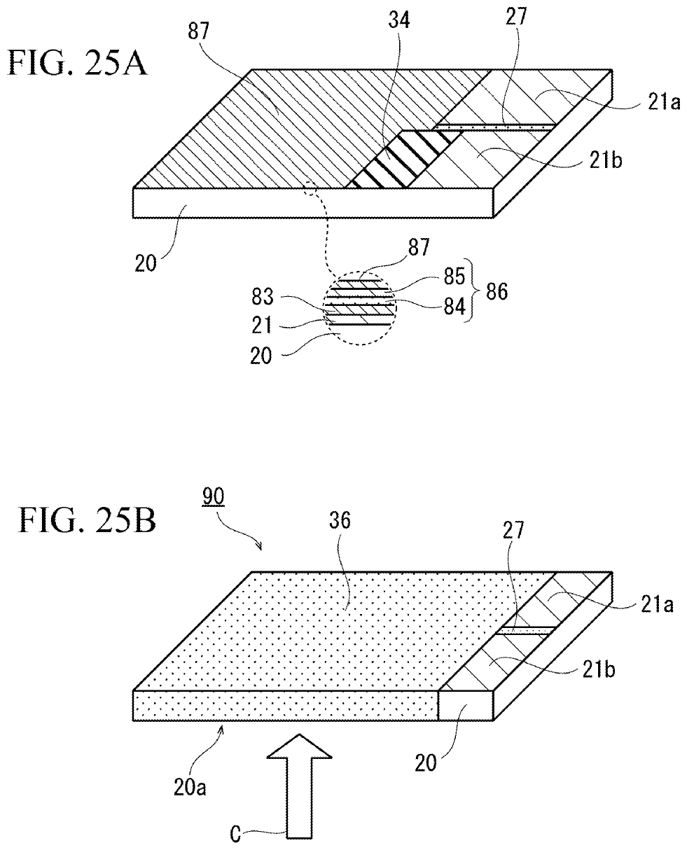

Next, as shown in FIG. 25A, a silver paste is applied, as a conductive paste 34, on the opposing electrode layer 87 and the second electrode 21b, respectively, and then solidified at temperatures between 50° C. and 150° C., such as 100° C. or so, to electrically connect the opposing electrode layer 87 and the second electrode 21b via the conductive paste 34.

Additionally, as shown in FIG. 25B, the opposing electrode layer 87 and the side faces of the transparent substrate 20 are covered with a UV-curable resin 36 in such a way that the first electrode 21a and second electrode 21b will be exposed. It should be noted that the first principal face 20a on which light C is incident is not covered with the UV-curable resin 36, but remains exposed. Thereafter, the UV-curable resin 36 is cured by irradiating ultraviolet light, to protect the transparent electrode layer 21, positive-electrode layer 83, organic generation layer 86, and opposing electrode layer 87 with the UV-curable resin 36, respectively. It should be noted that the center part of the principal face of the opposing electrode layer 87 may remain partially exposed, without being covered with the UV-curable resin 36.

The foregoing completes the basic structure of the organic photovoltaic cell 90 pertaining to this example. This organic photovoltaic cell 90 is an organic thin-film photovoltaic cell, as mentioned above, where light incident on the first principal face 20a of the transparent substrate 20 transmits through the transparent electrode layer 21 and positive-electrode layer 83, and reaches the organic generation layer 86, to produce an electromotive force between the positive-electrode layer 83 and the opposing electrode layer 87. It should be noted that, in this example, the first electrode 21a becomes a positive electrode, while the second electrode 21b becomes a negative electrode.

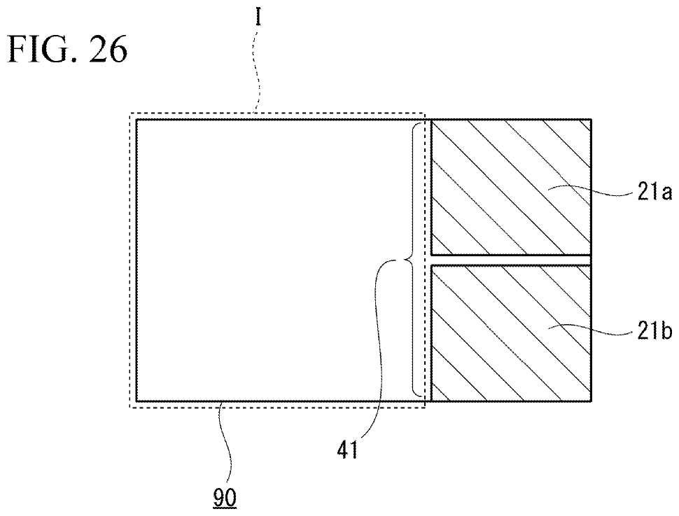

FIG. 26 is a schematic plan view of this organic photovoltaic cell 90. As shown in FIG. 26, the cell region I where all of the transparent electrode layer 21, organic generation layer 86, and opposing electrode layer 87 overlap one another in plan view is also rectangular in this example.

Additionally, the second electrode 21b is provided on the side of the organic photovoltaic cell 90 where the first electrode 21a is located, so that the electrodes 21a, 21b extend from one side 41 of the cell region Ito the outside of the cell region I. This makes it easy to connect and remove the electrodes 21a, 21b to/from the connector 50 (refer to FIG. 7), as in Examples 1 to 6.

### EXAMPLE 8

In this example, various examples of the mutual positional relationships of the cell region I, first electrode 21a, and second electrode 21b are explained.

### FIRST EXAMPLE

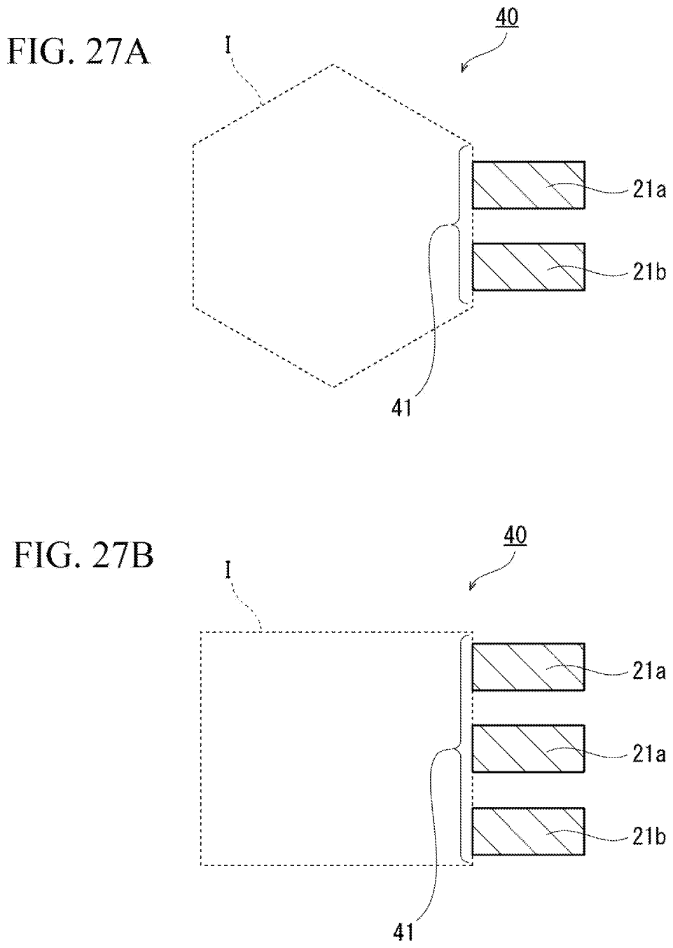

FIG. 27A is a schematic plan view of the organic photovoltaic cell 40 pertaining to the first example in this example. As shown in FIG. 27A, this example assumes the cell region I as a hexagon in plan view. Additionally, the second electrode 21b is led out to the side of the organic photovoltaic cell 40 where the first electrode 21a is located, so that the electrodes 21a, 21b extend to the outside of the cell region I from one side 41 of the six sides constituting the hexagon.

It should be noted that the planar shape of the cell region I is not limited to a hexagon, and it may be a pentagon, heptagon or other polygon having more sides. Also, the cell region I may be formed as a virtually polygonal shape having rounded apexes, corresponding to any of these polygons whose apexes have been chamfered. It should be noted further that, so long as the one side 41 on which the electrodes 21a, 21b are provided is a straight line, the contour of the cell region I along the side 41 may consist of a curved line. In some embodiments, when the planar shape of the cell region I is a polygon, the side 41 is constituted by adjacent two straight lines along the contour of the cell region, as long as the electrodes 21a, 21b are arranged in a side-by-side manner in plan view.

In addition, while this example is explained using the organic photovoltaic cell 40 pertaining to Example 1, this variation example may be applied to the organic photovoltaic cell 70, 80, 90 pertaining to Examples 2 to 7. The same can be said about the second variation example and third variation example described later.

### SECOND EXAMPLE

FIG. 27B is a schematic plan view of the organic photovoltaic cell 40 pertaining to the second example in this example. As shown in FIG. 27B, two first electrodes 21a are provided in this example to provide a total number of three electrodes 21a, 21b. In this case, too, the electrodes 21a, 21b are provided on the same side of the cell region I, so that the electrodes 21a, 21b extend from the same side 41 of the cell region I to the outside of the cell region I.

It should be noted that the total number of electrodes 21a, 21b is not limited to three, and it may be four or more.

### THIRD EXAMPLE

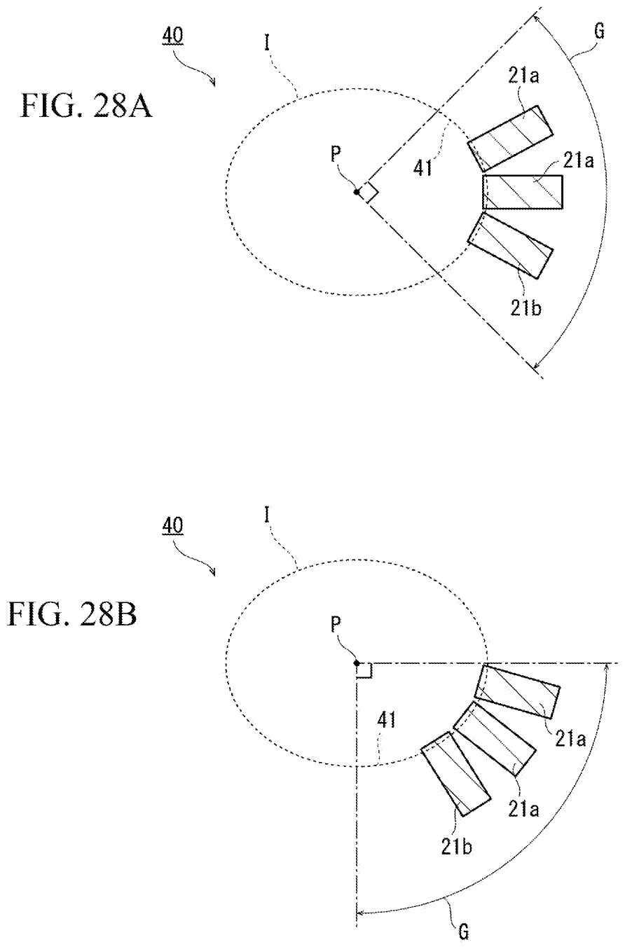

FIG. 28A is a schematic plan view of the organic photovoltaic cell 40 pertaining to the third example in this example. As shown in FIG. 28A, the cell region I is elliptical in plan view in this example. Additionally, the electrodes 21a, 21b are provided within an angle range G of 90° from the center P of the cell region I, so that the electrodes 21a, 21b are provided on the same side of the cell region I and that the electrodes 21a, 21b extend from this side 41 within the angle range G to the outside of the cell region I. It should be noted that the reference point of the angle range G is not limited to the center P, and the electrodes 21a, 21b may be positioned in its entirety or at least partially in an angle range G of 90° from any point inside the cell region I.

As described above, providing the electrodes 21a, 21b on the same side of the cell region I allows these electrodes 21a, 21b to be connected and removed to/from the connector 50 (refer to FIG. 7), even when the side 41 is a curved line, and this improves the convenience of the organic photovoltaic cell 40. It should be noted that, while this example provides a total number of three electrodes 21a, 21b, one first electrode 21a and one second electrode 21b may be provided to a total number of two electrodes 21a, 21b. Also, the planar shape of the cell region I is not limited to an ellipse, and the cell region I may be made a circle or made in a shape constituted by multiple continuous curved lines.

Furthermore, the positions of the electrodes 21a, 21b in the angle range G are not limited in any way, either. FIG. 28B is a schematic plan view of the organic photovoltaic cell 40 pertaining to another example of this variation example. In this example, one of the electrodes 21a, 21b is shifted toward an edge of the angle range G. Doing so still allows the electrodes 21a, 21b to be connected and removed to/from the connector 50 (refer to FIG. 7).

### EXAMPLE 9

In Example 7, the transparent electrode layer 21, positive-electrode layer 83, organic generation layer 86, and opposing electrode layer 87 were formed, in this order, on the transparent substrate 20, as shown in FIG. 24B, for example. In this example, the formation order of these layers is reversed.

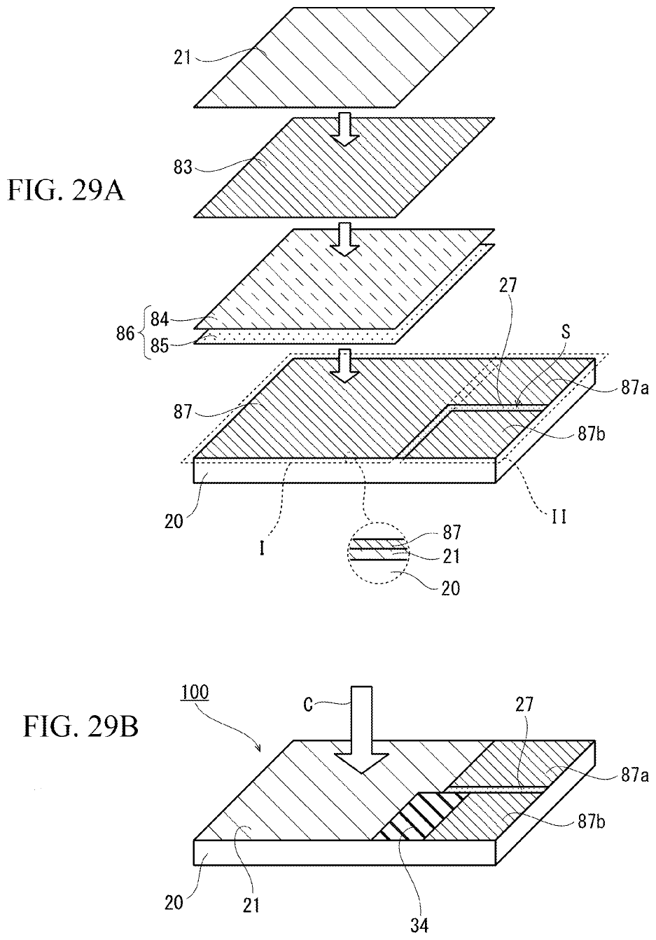

FIG. 29A and 29B are perspective views of the organic photovoltaic cell pertaining to this example in the process of being manufactured. First, as shown in FIG. 29A, a transparent substrate 20 is prepared on which a fluorine-doped tin oxide (FTO) layer has been formed, as a transparent electrode layer 21, to a thickness of approx. 0.1 μm to 0.5 μm beforehand. Then, a platinum layer is formed, as an opposing electrode layer 87, to a thickness of approx. 0.1 nm to 10 nm on the transparent electrode layer 21 using the sputtering method. Thereafter, the transparent electrode layer 21 and opposing electrode layer 87 are cut with a laser beam to form a slit S.

This forms a first electrode 87a constituted by a part of the opposing electrode layer 87 corresponding to the electrode region II, as if a part of the opposing electrode layer 87 corresponding to the cell region I of the transparent substrate 20 extends to the electrode region II while keeping the transparent electrode layer 21 intact. At the same time, the opposing electrode layer 87 in the portion isolated from the first electrode 87a by the slit S becomes a second electrode 87b.

Additionally, a UV-curable resin 27 is applied in the slit S and then ultraviolet light is irradiated to cure the UV-curable resin 27, to fill the slit S with the UV-curable resin. Thereafter, an acceptor layer 85 and a donor layer 84 are stacked, in this order, on the opposing electrode layer 87 in the cell region I in a manner similar to Example 7, to form an organic generation layer 86. Additionally, a conductive polymer is applied on the organic generation layer 86 and then dried to form a positive-electrode layer 83, after which a transparent electrode layer 21 is further formed thereon using the sputtering method. This transparent electrode layer 21 is an FTO layer with a thickness of 0.1 μm to 0.5 μm, for example.

Next, as shown in FIG. 29B, a conductive paste 34 is applied on the transparent electrode layer 21, which is the topmost layer, and on the second electrode 87b, respectively. Thereafter, the conductive paste 34 is heated and solidified to electrically connect the transparent electrode layer 21, which is the topmost layer, and the second electrode 87b. It should be noted that the heating temperature of the conductive paste 34 is not limited in any way, and the heating can be done at temperatures between 50° C. and 150° C., such as 100° C. or so.

The foregoing completes the basic structure of the organic photovoltaic cell 100 pertaining to this example. In this organic photovoltaic cell 100, incidence of light C from the transparent electrode layer 21 or specifically the topmost layer side generates an electromotive force in the organic generation layer 86, and this electric power can be drawn from the electrodes 87a, 87b.

In this example, too, the second electrode 87b is provided on the same side of the organic photovoltaic cell 100 as the first electrode 87a, which makes it easy to connect and remove these electrodes 87a, 87b to/from the connector (refer to FIG. 7), and the convenience of the organic photovoltaic cell 100 can be increased as a result.

We/I claim:

1. An organic photovoltaic cell comprising:
a transparent electrode layer;
an opposing electrode layer facing the transparent electrode layer;
an organic generation layer provided between the transparent electrode layer and the opposing electrode layer, wherein a region where the transparent electrode layer, the opposing electrode layer, and the organic generation layer overlap one another as viewed from above or in a thickness direction, i.e., in plan view, constitutes a cell region;
a first electrode electrically connected to the transparent electrode layer; and
a second electrode electrically connected to the opposing electrode layer and provided, in plan view, on a side of the cell region where the first electrode is located or along a contour of the cell region in a side-by-side manner.

2. The organic photovoltaic cell according to claim 1, wherein:
the cell region is a polygon in plan view; and
the first electrode and the second electrode each extend, in plan view, from a same side of the polygon to an outside of the cell region.

3. The organic photovoltaic cell according to claim 1, wherein:
the cell region has a curved side in plan view; and
the first electrode and the second electrode each extend, in plan view, from the side to an outside of the cell region.

4. The organic photovoltaic cell according to claim 3, wherein:
the first electrode and the second electrode are positioned, in plan view, within an angle range of 90° from a point inside the cell region.

5. The organic photovoltaic cell according to claim 4, wherein:
the cell region is a circle or ellipse, and the point inside the cell region corresponds to a center point of the circle or ellipse.

6. The organic photovoltaic cell according to claim 1, wherein:
further comprising a transparent substrate having a first principal face on which light is incident and a second principal face on which the transparent electrode layer is formed, wherein the first electrode and the second electrode are formed on the second principal face of the transparent substrate.

7. The organic photovoltaic cell according to claim 6, wherein:
the first electrode is formed by extending a part of the transparent electrode layer on the second principal face; and
the second electrode is positioned in a same plane with the transparent electrode layer.

8. The organic photovoltaic cell according to claim 6, wherein:
further comprising a supporting substrate that has been bonded to the transparent substrate via the opposing electrode layer, wherein the first electrode and the second electrode each remain exposed instead of being covered by the supporting substrate.
